(19) United States
(12) Patent Application Publication
(10) Pub. No.: US 2024/0381744 A1
(43) Pub. Date: Nov. 14, 2024

(54) DISPLAY PANEL AND METHOD FOR MANUFACTURING DISPLAY PANEL

(71) Applicants: KunShan Go-Visionox Opto-Electronics Co., Ltd, Kunshan (CN); Hefei Visionox Technology Co., Ltd., Hefei (CN)

(72) Inventors: Xiujian ZHU, Kunshan (CN); Guojun ZHANG, Kunshan (CN); Ying SHEN, Kunshan (CN); Pengle DANG, Kunshan (CN); Mingwei GE, Kunshan (CN); Lixiong XU, Kunshan (CN)

(73) Assignees: KunShan Go-Visionox Opto-Electronics Co., Ltd, Kunshan (CN); Hefei Visionox Technology Co., Ltd., Hefei (CN)

(21) Appl. No.: 18/756,044

(22) Filed: Jun. 27, 2024

Related U.S. Application Data
(63) Continuation of application No. PCT/CN2024/091624, filed on May 8, 2024.

(30) Foreign Application Priority Data
May 8, 2023 (CN) 202310507808.8

(51) Int. Cl. H10K 59/80; H10K 59/12; H10K 59/122

(52) U.S. Cl. CPC H10K 59/874; H10K 59/1201; H10K 59/122; H10K 59/873

(57) ABSTRACT

A display panel and a method for manufacturing a display panel. The display panel includes: a substrate; a dam structure disposed on the substrate and located in a transition area, and the dam structure being disposed surrounding at least a portion the transition area; a light-emitting layer disposed on the substrate and including a body portion located in the display area and a hollow portion penetrating through the body portion, and the hollow portion including a first vacant segment formed by a disconnect of the body portion in the aperture area and a second vacant segment located between the dam structure and the aperture area.

### CROSS-REFERENCE TO RELATED APPLICATION

The present application is a continuation application of International Application No. PCT/CN2024/091624, filed on May 8, 2024, which claims priority to Chinese Patent Application No. 202310507808.8 filed on May 8, 2023, both of which are incorporated herein by reference in their entireties.

### TECHNICAL FIELD

The present application relates to the field of display technology, and particularly, to a display panel and a method for manufacturing a display panel.

### BACKGROUND

A planar display panel such as a Liquid Crystal Display (LCD) panel, an Organic Light Emitting Diode (OLED) panel, and a display panel using a Light Emitting Diode (LED) device is widely used in various consumer electronic products such as a mobile phone, a TV, a personal digital assistant, a digital camera, a notebook computer, a desktop computer due to the advantages of high image quality, power saving, thin body and wide application range, and becomes the mainstream in the display apparatus.

In many existing display panels, an internal device of the display panel is susceptible to degradation caused by an external factor such as external moisture.

### SUMMARY

Embodiments of the present application provide a display panel and a method for manufacturing a display panel, aiming to restrict external moisture from diffusing into the display panel.

Embodiments of a first aspect of the present application provides a display panel having a display area, an aperture area, and a transition area surrounding at least a portion of the aperture area, and the display panel further includes: a substrate; a dam structure disposed on the substrate and located in the transition area, and the dam structure being disposed surrounding at least a portion of the aperture area; and a light-emitting layer disposed on the substrate and including a body portion located in the display area and a hollow portion penetrating through the body portion, and the hollow portion including a first vacant segment formed by a disconnect of the body portion in the aperture area and a second vacant segment located between the dam structure and the aperture area.

Embodiments of the first aspect of the present application further provide a display panel having a display area, an aperture area, and a transition area surrounding at least a portion of the aperture area, and the display panel further includes: a substrate; a pixel definition layer disposed at one side of the substrate and including a first pixel definition portion located in the display area, a pixel opening enclosed and formed by the first pixel definition portion, and a second pixel definition portion located in the transition area; an isolation structure disposed at one side of the first pixel definition portion located in the display area; a dam structure disposed on the substrate and located in the transition area, and the dam structure being disposed surrounding at least a portion of the aperture area; a light-emitting layer disposed on the substrate; and an encapsulation layer disposed at a side of the light-emitting layer away from the substrate and including a first encapsulation layer, and at least a portion of the first encapsulation layer being located in the transition area and abutting against a surface of the second pixel definition portion at a side away from the substrate.

Embodiments of a second aspect of the present application further provide a method for manufacturing a display panel, and the method includes: arranging a dam structure and a light-emitting material layer in sequence on a substrate; arranging a photoresist at a side of the light-emitting material layer located in a display area away from the substrate; and patterning the light-emitting material layer to form a body portion of a light-emitting layer, so that portions of the light-emitting material layer located in an aperture area and located between the dam structure and the aperture area are removed to form a first vacant segment and a second vacant segment.

### BRIEF DESCRIPTION OF THE DRAWINGS

FIG. 1 shows a schematic structural diagram of a display panel according to an embodiment of the present application;

FIG. 2 shows a partial cross-sectional diagram at I in FIG. 1 according to an embodiment of the present application;

FIG. 3 shows a partial cross-sectional diagram at I in FIG. 1 according to another embodiment of the present application;

FIG. 4 shows a partial cross-sectional diagram at I in FIG. 1 according to yet another embodiment of the present application;

FIG. 5 shows a partial cross-sectional diagram at I in FIG. 1 according to yet another embodiment of the present application;

FIG. 6 shows a partial cross-sectional diagram at I in FIG. 1 according to yet another embodiment of the present application;

FIG. 7 shows a partial cross-sectional diagram at I in FIG. 1 according to yet another embodiment of the present application;

FIG. 8 shows a partial cross-sectional diagram at I in FIG. 1 according to yet another embodiment of the present application;

FIG. 9 shows a partial cross-sectional diagram at I in FIG. 1 according to yet another embodiment of the present application;

FIG. 10 shows a schematic flow chart of a method for manufacturing a display panel according to an embodiment of the present application;

FIG. 11 to FIG. 17 show manufacturing process schematic diagrams of a method for manufacturing a display panel according to an embodiment of the present application; and

FIG. 18 to FIG. 21 show manufacturing process schematic diagrams of a method for manufacturing a display panel according to another embodiment of the present application.

### DETAILED DESCRIPTION

In an electronic device such as a cell phone or a tablet computer, a photosensitive component such as a front camera, an infrared light sensor, and a proximity light sensor is required to be integrated at a side of the display panel. In some embodiments, an aperture area may be disposed in the electronic device, and the photosensitive component may be disposed in the aperture area.

The display panel includes a substrate, a light-emitting layer disposed on the substrate, and an encapsulation layer configured to encapsulate the light-emitting layer. The light-emitting layer includes an organic light-emitting material, and the encapsulation layer also includes an organic material. Since the aperture area of the display panel is vulnerable to external moisture, the external moisture may soak into the organic material, on the one hand, the external moisture may diffuse through the organic material into the display area of the display panel to affect the display of the display panel, and on the other hand, the organic material absorbs water and may swell, resulting in film layer peeling-off, and causing a problem such as insufficient sealing.

In order to solve the above problems, the embodiments of the present application provide a display panel and a method for manufacturing the display panel, which will be described below with reference to the drawings.

As shown in FIG. 1, the embodiments of the present application provide a display panel 10, which may be an organic light emitting diode (OLED) display panel.

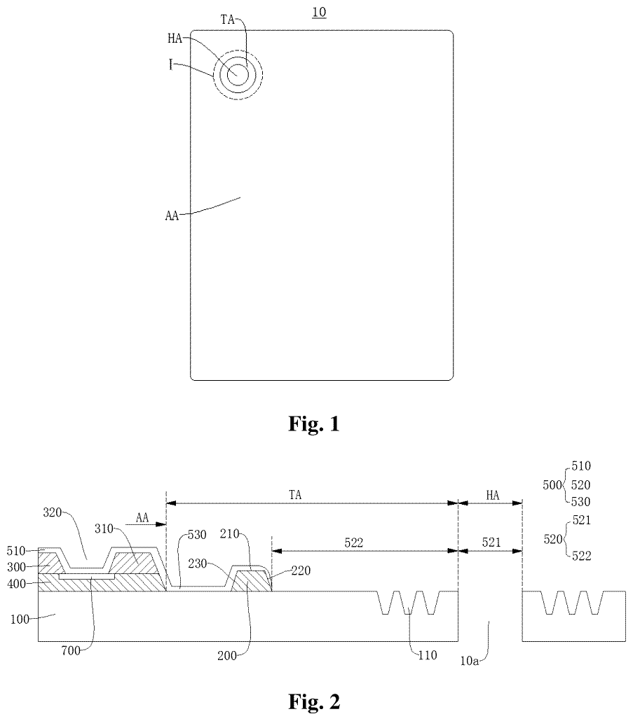

As shown in FIG. 1 and FIG. 2, the embodiments of the first aspect of the present application provides a display panel 10 including a display area AA, an aperture area HA, and a transition area TA surrounding at least a portion of the aperture area HA, and the display panel 10 further includes: a substrate 100; a dam structure 200 disposed on the substrate 100 and located in the transition area TA, in which the dam structure 200 is disposed surrounding at least a portion of the aperture area HA; and a light-emitting layer 500 disposed on the substrate 100 and including a body portion 510 located in a display area AA and a hollow portion 520 penetrating through the body portion 510, in which the hollow portion 520 includes a first vacant segment 521 formed by a disconnect of the body portion 510 in the aperture area HA and a second vacant segment 522 located between the dam structure 200 and the aperture area HA.

The dam structure 200 is disposed surrounding at least a portion of the aperture area HA, so that the dam structure 200 can be configured to prevent flowing of an encapsulation material, that is, the dam structure 200 can be configured to restrict at least a portion of the encapsulation material located at a side of the dam structure 200 facing the display area AA from flowing towards the aperture area HA; and the light-emitting layer 500 is disposed on the substrate 100 and includes the body portion 510 and the hollow portion 520 penetrating through the body portion 510, and the second vacant segment 522 is formed by a disconnect of the light-emitting layer 500 between the dam structure 200 and the aperture area HA, so that the external moisture in the aperture area HA is less likely to soak into the light-emitting layer 500 of the display area AA due to water absorption of the material of the light-emitting layer 500, and thus the external moisture is less likely to diffuse to the display area AA of the display panel 10 through the light-emitting layer 500 to affect operation of the display panel 10, and the external moisture is better restricted from diffusing into the display panel.

In some optional embodiments, the transition area TA may surround the aperture area HA and be located between the aperture area HA and the display area AA, so that the transition area TA of the display panel 10 can better restrict the external moisture in the aperture area HA from soaking into the display area AA, thereby increasing operational reliability of the display panel 10.

In some optional embodiments, the dam structure 200 may be disposed in various ways. For example, the dam structure 200 may be disposed continuously, and the dam structure 200 is disposed surrounding at least the portion of the aperture area HA, so that the dam structure 200 is disposed between the aperture area HA and the display area AA for blocking the encapsulation material, so that the encapsulation material is less likely to flow towards the aperture area HA.

The thickness of the body portion 510 is greater than 0, that is, a distance between a surface of the body portion 510 at a side away from the substrate 100 and a surface of the body portion 510 at a side facing the substrate 100 is greater than 0. The hollow portion 520 penetrates through the body portion 510, and the thickness of the hollow portion 520 is 0, that is, the hollow portion 520 is vacant and provided with no film layer structure.

In some optional embodiments, the light-emitting layer 500 further includes a bulk portion 530, and the bulk portion 530 may be disposed on the substrate 100 or the dam structure 200 in the transition area TA on which no hollow portion 520 is disposed. For example, the bulk portion 530 may be disposed between the substrate 100 or the dam structure 200 and the display area AA. Optionally, the bulk portion 530 may be made of the same material and manufactured in the same process as the body portion 510, and the bulk portion 530 may be manufactured in the same manufacturing step as the body portion 510.

In the embodiment, the hollow portion 520 is an area enclosed and formed by an inner wall surface of the body portion 510 or the bulk portion 530 at a side facing the aperture area.

Optionally, the material of the light-emitting layer 500 may include an organic material, for example, the light-emitting layer 500 may include a hole inject layer (HIL), a hole transport layer (HTL), a light-emitting structure, an electron inject layer (EIL), and an electron transport layer (ETL) that are stacked. Optionally, the display panel 10 further includes a first electrode layer disposed at a side of the light-emitting layer 500 away from the substrate 100, the material of the first electrode layer may further include a metal material, and the first electrode layer may be used as an anode or a cathode to drive the light-emitting structure to emit light. Optionally, the first electrode layer is disconnected at least in the aperture area HA to form a portion located outside the aperture area HA.

Optionally, the first electrode layer at the hollow portion 520 is disconnected, that is, the thickness of the first electrode layer at the hollow portion 520 is 0, so that the first electrode layer is less likely to contact with the external moisture in the aperture area HA, thereby increasing the operation reliability of the display panel 10.

Optionally, the first electrode layer may be disconnected in the transition area TA to form a portion located only in the display area AA, so as to further increase the operational reliability of the display panel 10.

The display panel 10 includes a via 10a or a blind via located in the aperture area HA to integrate a photosensitive component in the aperture area HA, for example, to integrate a photosensitive component such as a front camera, an infrared light sensor, and a proximity light sensor. For ease of explanation, in the following embodiments, for example, the display panel 10 includes the via 10a located in the aperture area HA.

By arranging the second vacant segment 522 of the hollow portion 520 between the dam structure 200 and the aperture area HA, the external moisture cannot soak into the light-emitting layer 500 through the via 10a, so that the external moisture is better restricted from diffusing into the display panel 10.

Optionally, the first vacant segment 521 is communicated with the second vacant segment 522 to enhance the diffusion path of the external moisture diffusing to the body portion 510, thereby reducing the effect of the external moisture on the operational reliability of the display panel 10.

In some optional embodiments, an orthographic projection of the dam structure 200 on the substrate 100 has an edge at a side facing the aperture area HA, and the bulk portion 530 may be located at a side of the edge away from the aperture area HA, so as to increase the extension size of the second vacant segment 522 along a direction from the dam structure 200 to the aperture area HA, which greatly enhance the diffusion path of the external moisture diffusing to the body portion 510, so that the external moisture is less likely to diffuse to the dam structure 200 and less likely to diffuse to a layer structure or device such as the encapsulation material at a side of the dam structure 200 away from the aperture area HA, and thus the external moisture is less likely to soak into the body portion 510 to contact with the organic material in the light-emitting layer 500, thereby reducing the effect of the external moisture on the operational reliability of the display panel 10.

Optionally, no film layer structure of the light-emitting layer 500 is disposed between the dam structure 200 and the aperture area HA, so that external water vapor is less likely to diffuse in the transition area TA between the dam structure 200 and the aperture area HA, and thus the external water vapor is less likely to diffuse to the display area AA of the display panel 10 to affect the display of the display panel 10.

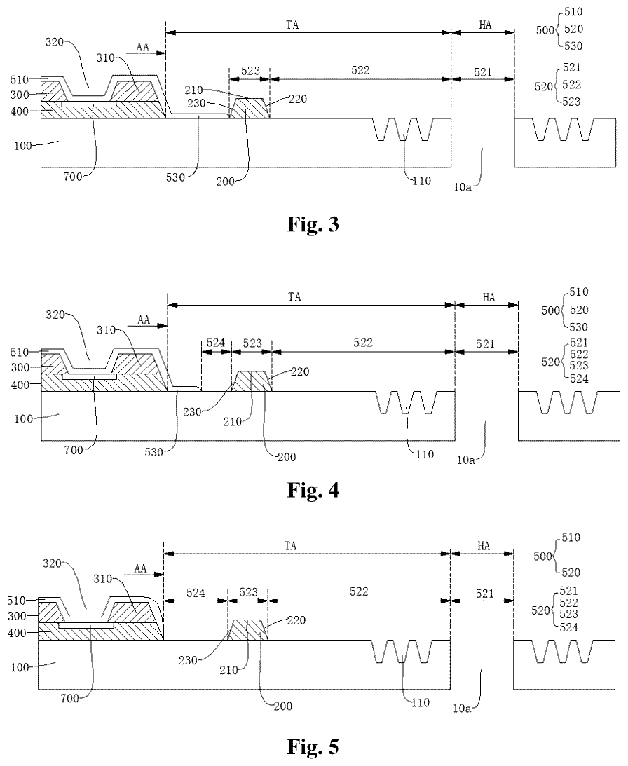

As shown in FIG. 3, in some optional embodiments, the hollow portion 520 further includes a third vacant segment 523, and at least a portion of the dam structure 200 is exposed from the third vacant segment 523.

At least a portion of the dam structure 200 being exposed from the third vacant segment may mean that the bulk body 530 does not completely cover the dam structure 200, or that the bulk portion 530 does not cover the dam structure 200.

By arranging the third vacant segment 523 at a side of the dam structure 200 away from the substrate 100, the external moisture is further less likely to diffuse to a layer structure or device such as the encapsulation material at a side of the dam structure 200 away from the aperture area HA and the body portion 510, and the effect of the external moisture on the operational reliability of the display panel 10 is reduced.

In some optional embodiments, the location of the third vacant segment 523 on the dam structure 200 and the shape of the third vacant segment 523 may be set in various manners. Optionally, the dam structure 200 includes a first surface 210 located at a side away from the substrate 100, and a second surface 220 and a third surface 230 connected between the first surface 210 and the substrate 100, in which the second surface 220 is located at a side of the third surface 230 away from the display area AA. The third vacant segment 523 may be disposed at at least one of the first surface 210, the second surface 220, or the third surface 230.

Optionally, the third vacant segment 523 may be disposed surrounding at least a portion of the second vacant segment 522, so that at least a portion of the external moisture passing through the second vacant segment 522 further needs to pass through the third vacant segment 523 to soak into the layer structure or device such as the encapsulation material and the body portion 510 of the display panel 10, and thus the external moisture is less likely to diffuse within the organic material in the display panel 10 to further restrict the external moisture from diffusing into the display panel 10.

Optionally, the third vacant segment 523 may be communicated with the second vacant segment 522, that is, at least a portion of the third vacant segment 523 is disposed on the second surface 220 and communicated with the second vacant segment 522 to further enhance the diffusion path of the external moisture diffusing to the body portion 510, so that the external moisture is less likely to contact with the organic material in the light-emitting layer 500.

Optionally, the first surface 210, the second surface 220, and the third surface 230 of the dam structure 200 are all exposed from the third vacant segment 523 to further enhance the diffusion path of the external moisture diffusing to the body portion 510, so that the external moisture is less likely to contact with the organic material in the light-emitting layer.

As shown in FIG. 4, in some optional embodiments, the hollow portion 520 further includes a fourth vacant segment 524 located between the dam structure 200 and the display area AA. By arranging the fourth vacant segment 524 between the dam structure 200 and the display area AA, the external moisture is further less likely to diffuse to the display area AA of the display panel 10, and the effect of the external moisture on the display of the display panel 10 is reduced.

In some optional embodiments, the location of the fourth vacant segment 524 between the dam structure 200 and the display area AA and the shape of the fourth vacant segment 524 may be set in various manners. Optionally, the fourth vacant segment 524 is disposed surrounding at least a portion of the second vacant segment 522, or the fourth vacant segment 524 may be disposed surrounding at least a portion of the third vacant segment 523. Therefore, at least a portion of the external moisture passing through the second vacant segment 522 or passing through the third vacant segment 523 further needs to pass through the fourth vacant segment 524 to soak into the organic material in the body portion 510 of the light-emitting layer 500, so that the external moisture is less likely to diffuse within the organic material in the display panel 10 to the display area AA, so as to reduce the effect of the external moisture on the display of the display panel 10.

Optionally, the fourth vacant segment 524 is communicated with the third vacant segment 523 to further extend the diffusion path of the external moisture diffusing to the body portion 510, so that the external moisture is less likely to diffuse to the display area AA of the display panel 10.

As shown in FIG. 5, optionally, no film layer structure of the light-emitting layer 500 is disposed between the dam structure 200 and the display area AA, so that the external water vapor is less likely to diffuse in the transition area TA between the dam structure 200 and the display area AA, and thus the external water vapor is less likely to diffuse to the display area AA of the display panel 10 to affect the display of the display panel 10.

As shown in FIG. 5, in these optional embodiments, the display panel 10 further includes a pixel definition layer 300 disposed at one side of the substrate 100, the pixel definition layer 300 includes a first pixel definition portion 310 located in the display area AA and a pixel opening 320 enclosed and formed by the first pixel definition portion 310, and at least a portion of the body portion 510 is disposed in the pixel opening 320. For example, at least a portion of the body portion 510 is disposed at a side of the pixel definition layer 300 away from the substrate 100 and located within the pixel opening 320, and the first pixel definition portion 310 may be configured to divide the sub-pixels of the display panel 10.

Optionally, the display panel 10 further includes a planarization layer 400 disposed at one side of the substrate 100, the pixel definition layer 300 is located at a side of the planarization layer 400 away from the substrate 100, and the dam structure 200 may be disposed in the same layer and made of the same material as the planarization layer 400, so that the manufacturing process of the display panel 10 is further simplified, and the manufacturing efficiency of the display panel 10 is increased.

As shown in FIG. 5, the display panel 10 further includes a second electrode layer 700 disposed correspondingly to the pixel opening 320, one of the first electrode layer and the second electrode layer 700 is used as an anode, and the other one is used as a cathode, so as to drive the light-emitting structure to emit light. In the embodiments of the present application, for example, the first electrode layer is the cathode of the display panel 10, and the second electrode layer 700 is the anode of the display panel 10.

An edge of an orthographic projection of the display area AA on the substrate 100 facing the dam structure 200 may refer to an edge of an orthographic projection of the first pixel definition portion 310, which is located at a side of the display area AA facing the dam structure 200, on the substrate 100 facing the dam structure 200, or an edge of an orthographic projection of the planarization layer 400, which is located at the side of the display area AA facing the dam structure 200, on the substrate 100 facing the dam structure 200.

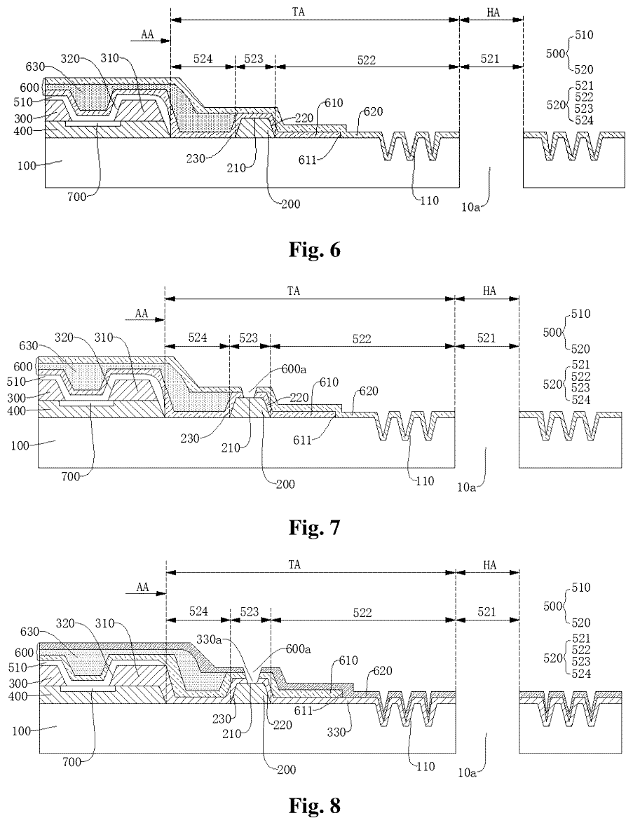

As shown in FIG. 6, in some optional embodiments, the display panel 10 further includes an encapsulation layer 600 disposed at a side of the light-emitting layer 500 away from the substrate 100, the encapsulation layer 600 includes a first encapsulation layer 610, and an end portion 611 of the first encapsulation layer 610 at a side facing the aperture area HA is spaced apart from the aperture area HA.

In these optional embodiments, the first encapsulation layer 610 can be configured to encapsulate the light-emitting layer 500, and by spacing apart the end portion 611 of the first encapsulation layer 610 at the side facing the aperture area HA from the aperture area HA, the external moisture in the aperture area HA is less likely to diffused to the first encapsulation layer 610, and thus the first encapsulation layer 610 is less likely to be affected by water erosion, thereby improving the encapsulation effect of the first encapsulation layer 610.

In some optional embodiments, the first encapsulation layer 610 may extend from the display area AA to the transition area TA to better extend the encapsulation path of the first encapsulation layer 610, thereby further improving the encapsulation effect of the first encapsulation layer 610.

Optionally, a portion of the first encapsulation layer 610 may be located at a side of the dam structure 200 away from the substrate 100. Optionally, the first encapsulation layer 610 may extend from the display area AA to a side of the dam structure 200 facing the aperture area HA. By extending the first encapsulation layer 610 to the dam structure 200, the encapsulation path of the first encapsulation layer 610 can be further enhanced, thereby improving the encapsulation effect of the first encapsulation layer 610.

Optionally, the material of the first encapsulation layer 610 may be an inorganic material, for example, the material of the first encapsulation layer 610 includes silicon oxynitride.

Optionally, the first electrode layer is located at a side of the light-emitting layer 500 away from the substrate 100, and the first encapsulation layer 610 covers the first electrode layer, so that the first encapsulation layer 610 can also be configured to encapsulate the first electrode layer.

As shown in FIG. 6, in some optional embodiments, the encapsulation layer 600 further includes a second encapsulation layer 620 disposed at a side of the first encapsulation layer 610 away from the substrate 100, and at least a portion of the second encapsulation layer 620 covers the substrate 100 between the end portion 611 of the first encapsulation layer 610 at the side facing the aperture area HA and the aperture area HA.

In these optional embodiments, by arranging at least a portion of the second encapsulation layer 620 to cover the substrate 100 between the end portion 611 of the first encapsulation layer 610 at the side facing the aperture area HA and the aperture area HA, the second encapsulation layer 620 can prevent the contact between at least a portion of the external moisture and the first encapsulation layer 610, so that the external moisture is further less likely to affect the encapsulation effect of the first encapsulation layer 610.

In some optional embodiments, the second encapsulation layer 620 may extend from the display area AA to the transition area TA, and the second encapsulation layer 620 located in the display area AA may participate in the encapsulation of the body portion 510. By arranging the second encapsulation layer 620 to extend from the display area AA to the transition area TA, the second encapsulation layer 620 may have a relatively long encapsulation path, thereby further improving the encapsulation effect of the second encapsulation layer 620.

Optionally, a portion of the second encapsulation layer 620 may be located at the side of the dam structure 200 away from the substrate 100. Optionally, the second encapsulation layer 620 may extend from the display area AA to the side of the dam structure 200 facing the aperture area HA. By arranging the second encapsulation layer 620 to extend to the dam structure 200, the encapsulation path of the second encapsulation layer 620 can be further enhanced, thereby improving the encapsulation effect of the second encapsulation layer 620.

Optionally, an edge of at least a portion of an orthographic projection of the second encapsulation layer 620 on the substrate 100 overlaps an edge of at least a portion of an orthographic projection of the aperture area HA on the substrate 100, so as to further restrict the external moisture in the aperture area HA from diffusing to the first encapsulation layer 610.

Optionally, the material of the second encapsulation layer 620 may be an inorganic material, for example, the material of the second encapsulation layer 620 includes silicon nitride. The material of the second encapsulation layer 620 is silicon nitride, so that the second encapsulation layer 620 has better stability compared to the first encapsulation layer 610, that is, the second encapsulation layer 620 is less likely to be affected by the moisture, and has better water erosion resistance.

As shown in FIG. 6, optionally, the encapsulation layer 600 further includes a third encapsulation layer 630 disposed between the first encapsulation layer 610 and the second encapsulation layer 620, the third encapsulation layer 630 may be located at a side of the dam structure 200 facing the display area AA, the material of the third encapsulation layer 630 may include an organic material, and the third encapsulation layer 630 may adjust the overall thickness of the encapsulation layer 600, so that the surface of the encapsulation layer 600 away from the substrate 100 is smoother. The dam structure 200 may be configured to block the material of the third encapsulation layer 630, so that the material of the third encapsulation layer 630 is less likely to flow towards the aperture area HA.

As shown in FIG. 6, in some optional embodiments, the substrate 100 includes an isolation groove 110 at a side facing the light-emitting layer 500, the isolation groove 110 can be configured to restrict extension of a crack, so that the crack is less likely to extend to the display area AA, so as to increase the operational reliability of the display panel 10.

Optionally, the isolation groove 110 may be disposed surrounding at least a portion of the aperture area HA to further improve the isolation effect of the isolation groove 110 on the crack.

Optionally, the substrate 100 may include a plurality of isolation grooves 110, and the plurality of isolation grooves 110 are disposed at intervals along a direction from the aperture area HA towards the display area AA, so as to further improve the isolation effect of the isolation groove 110 on the crack.

Optionally, at least a portion of the isolation groove 110 is located between the end portion 611 of the first encapsulation layer 610 at the side facing the aperture area HA and the aperture area HA, so that the isolation groove 110 may be configured to restrict the crack from extending towards the first encapsulation layer 610, thereby improving the encapsulation effect and encapsulation reliability of the first encapsulation layer 610.

As shown in FIG. 7, in some optional embodiments, a first air hole 600a is disposed in the encapsulation layer 600 located at the side of the dam structure 200 away from the substrate 100. For example, the first air hole 600a may be disposed in the first encapsulation layer 610 located at the side of the dam structure 200 away from the substrate 100, or the first air hole 600a may be disposed in the second encapsulation layer 620 located at the side of the dam structure 200 away from the substrate 100.

By arranging the first air hole 600a in the encapsulation layer 600 located at the side of the dam structure 200 away from the substrate 100, gas under the encapsulation layer 600 may be exhausted through the first air hole 600a in the manufacturing process of the display panel 10.

As shown in FIG. 8, in some optional embodiments, the pixel definition layer 300 may further include a second pixel definition portion 330 located in the transition area TA, and the second pixel definition portion 330 located in the transition area TA may also be configured to restrict the external moisture in the aperture area HA from intruding into the display area AA.

Optionally, the material of the second pixel definition portion 330 may include an inorganic material, for example, the material of the second pixel definition portion 330 may include silicon nitride, so that the second pixel definition portion 330 may have better stability, that is, the second pixel definition portion 330 is less likely to be affected by the moisture, and has better water erosion resistance.

In some optional embodiments, the second pixel definition portion 330 may be connected to the first pixel definition portion 310, and the second pixel definition portion 330 and the first pixel definition portion 310 are made of a same material and manufactured in a same process, so that the second pixel definition portion 330 may be manufactured in the same manufacturing process as the first pixel definition portion 310, so as to further increase the manufacturing efficiency of the display panel 10.

Optionally, a portion of the second pixel definition portion 330 may be located at a side of the dam structure 200 away from the substrate 100. Optionally, the second pixel definition portion 330 may extend from a side of the dam structure 200 facing the display area AA to a side of the dam structure 200 facing the aperture area HA. By arranging the second pixel definition portion 330 to extend to the dam structure 200, restriction effect of the second pixel definition portion 330 on water vapor can be further improved.

Optionally, a second air hole 330a may be disposed in the second pixel definition portion 330 located at the side of the dam structure 200 away from the substrate 100, so that gas under the pixel definition layer 300 may be exhausted through the second air hole 330a in the manufacturing process of the display panel 10.

In some optional embodiments, at least a portion of the encapsulation layer 600 may extend to the transition area TA and abut against a surface of the second pixel definition portion 330 at a side away from the substrate 100.

Optionally, the first encapsulation layer 610 extends from the display area AA to the transition area TA, and the first encapsulation layer 610 located in the transition area TA abuts against at least a portion of the surface of the second pixel definition portion 330 at the side away from the substrate 100.

In these optional embodiments, by arranging at least a portion of the encapsulation layer 600 to extend to the transition area TA and abut against the surface of the second pixel definition portion 330 at the side away from the substrate 100, the encapsulation layer 600 and the second pixel definition portion 330 that are stacked may better restrict the moisture in the aperture area HA from intruding into the display area AA, thereby further improving the encapsulation effect of the display panel 10.

Optionally, at least a portion of the second encapsulation layer 620 may be located above the substrate 100 between the end portion 611 of the first encapsulation layer 610 at the side facing the aperture area HA and the aperture area HA, and the second encapsulation layer 620 located between the end portion 611 of the first encapsulation layer 610 at the side facing the aperture area HA and the aperture area HA may abut against at least a portion of the surface of the second pixel definition portion 330 at the side away from the substrate 100, so that the second encapsulation layer 620 can abut against the second pixel definition portion 330 to restrict the water vapor from soaking into the display area AA and further prevent the contact between at least a portion of the external moisture and the first encapsulation layer 610, and thus the external moisture is less likely to affect the encapsulation effect of the first encapsulation layer 610.

Optionally, a portion of the second pixel definition portion 330 may be stacked with and abut against the second encapsulation layer 620 within the isolation groove 110, so that the second pixel definition portion 330 and the second encapsulation layer 620 may have better continuity within the isolation groove 110 and better restrict the water vapor from intruding into the display area AA through the isolation groove 110, so as to further improve the encapsulation effect of the display panel 10.

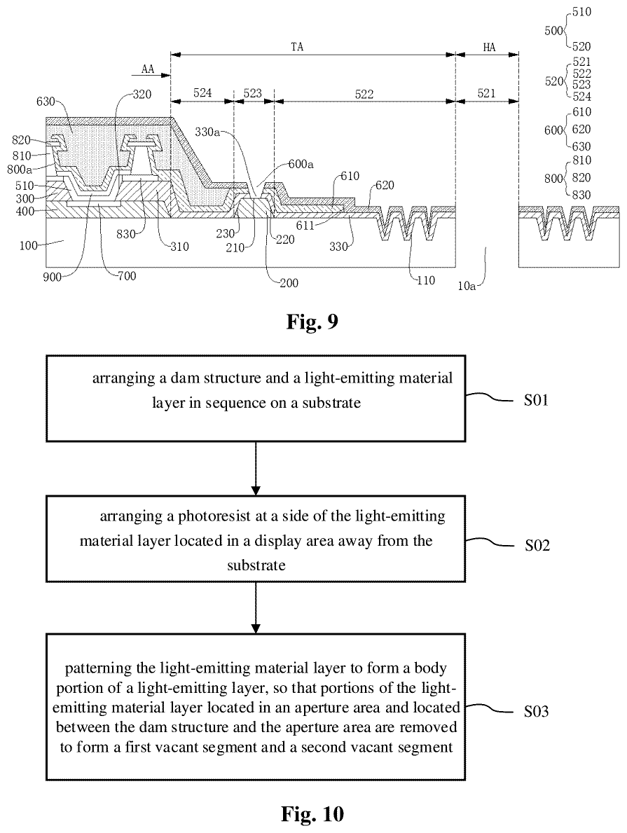

As shown in FIG. 9, the display panel 10 may further include an isolation structure 800, and the isolation structure 800 may be disposed at one side of the first pixel definition portion 310 located in the display area AA. For example, the isolation structure 800 may be disposed at a side of the first pixel definition portion 310 away from the substrate 100 and abut against the side of the first pixel definition portion 310 away from the substrate 100.

In some optional embodiments, the isolation structure 800 may enclose and form an isolation opening 800a communicated with the pixel opening 320, a portion of the body portion 510 may be located within the isolation opening 800a, and the isolation structure 800 may also be configured to divide the sub-pixels of the display panel 10.

Optionally, the isolation structure 800 include a first isolation portion 810 and a second isolation portion 820 located at a side of the first isolation portion 810 away from the substrate 100, and the second isolation portion 820 may protrude from the first isolation portion 810 towards the isolation opening 800a.

By arranging the second isolation portion 820 to protrude from the first isolation portion 810 towards the isolation opening 800a, when the material of the light-emitting layer 500 of the display panel 10 is vapor deposited, the second isolation portion 820 can block at least a portion of the material for manufacturing the light-emitting layer 500 to disconnect the material of the body portion 510 between adjacent sub-pixels, so that a plurality of body portions 510 disposed at intervals can be formed, and thus no metal mask with relatively high accuracy is needed when the material of the light-emitting layer 500 of the display panel 10 is vapor deposited. For example, no fine metal mask (FMM) is needed when the material of the light-emitting layer 500 of the display panel 10 is vapor deposited, and thus the manufacturing cost of the display panel 10 can be reduced.

In some optional embodiments, as shown in FIG. 9, a first electrode layer 900 may be used as the cathode of the display panel 10, the material of the isolation structure 800 includes an electrically conductive material, and the first electrode layer 900 may be connected to the isolation structure 800, so that the first electrode layers 900 of adjacent sub-pixels may be electrically connected to each other through the isolation structure 800, that is, the first electrode layers 900 of adjacent sub-pixels may be electrically connected to each other through the isolation structure 800 to form a planar electrode, thereby facilitating the control on the first electrode layer 900 in the display panel 10.

Optionally, the isolation structure 800 further includes a third isolation portion 830, the third isolation portion 830, the first isolation portion 810, and the second isolation portion 820 are stacked in sequence along a direction away from the substrate 100, and the third isolation portion 830 may protrude from the first isolation portion 810 towards the isolation opening 800a and be connected to the first electrode layer 900, so as to better increase connection stability between the isolation structure 800 and the first electrode layer 900.

Optionally, at least a portion of the first encapsulation layer 610 covers a surface of the isolation structure 800 to improve the encapsulation effect of the first encapsulation layer 610.

In some optional embodiments, the material of the pixel-definition layer 300 may include an inorganic material, so that the pixel-definition layer 300 is less likely to absorb water, and thus the pixel-definition layer 300 is less likely to absorb water and swell due to an etching material in the manufacturing process of the display panel 10. For example, the pixel-definition layer 300 is less likely to absorb water and swell due to the etching material in the manufacturing process of the isolation structure 800.

Referring to FIG. 1 to FIG. 9, the embodiments of the first aspect of the present application further provide a display panel 10 including a display area AA, an aperture area HA, and a transition area TA surrounding at least a portion of the aperture area HA, and the display panel 10 further includes: a substrate 100; a pixel definition layer 300 disposed at one side of the substrate 100 and including a first pixel definition portion 310 located in the display area AA, a pixel opening 320 enclosed and formed by the first pixel definition portion 310, and a second pixel definition portion 330 located in the transition area TA; an isolation structure 800 disposed at one side of the first pixel definition portion 310 located in the display area AA; a dam structure 200 disposed on the substrate 100 and located in the transition area TA, in which the dam structure 200 is disposed surrounding at least a portion of the aperture area HA; a light-emitting layer 500 disposed on the substrate 100; and an encapsulation layer 600 disposed at a side of the light-emitting layer 500 away from the substrate 100 and including a first encapsulation layer 610, in which at least a portion of the first encapsulation layer 610 is located in the transition area TA and abuts against a surface of the second pixel definition portion 330 at a side away from the substrate 100.

In the display panel 10 further according to the embodiments of the first aspect of the present application, the first pixel definition portion 310 of the pixel definition layer 300 and the isolation structure 800 disposed at one side of the first pixel definition portion 310 may be both configured to divide the sub-pixels of the display panel 10, and the isolation structure 800 may be configured to disconnect the light-emitting layers 500 of adjacent sub-pixels. The encapsulation layer 600 may be configured to encapsulate the light-emitting layer 500 to restrict the effect of the moisture on the light-emitting layer 500. At least a portion of the first encapsulation layer 610 is located in the transition area TA and abuts against the surface of the second pixel definition portion 330 at the side away from the substrate 100, so that the second pixel definition portion 330 and the first encapsulation layer 610 may be stacked to collectively restrict the water vapor in the aperture area HA from intruding into the display area AA, so as to better improve the encapsulation effect of the display panel 10.

Optionally, the display panel 10 further according to the embodiments of the first aspect of the present application may be the display panel 10 in any one of the above embodiments, and thus the display panel 10 further according to the embodiments of the present application may have the structures and beneficial effects of the display panel 10 in any one of the above embodiments, which are not repeated in the present application.

For example, the isolation structure 800 may be the isolation structure 800 in any one of the above embodiments, and the isolation structure 800 may include the first isolation portion 810, the second isolation portion 820, and the third isolation portion 830 in any one of the above embodiments. For example, the light-emitting layer 500 may be the light-emitting layer 500 in any one of the above embodiments, and the light-emitting layer 500 may include the body portion 510, the hollow portion 520, and the bulk portion 530 in any one of the above embodiments. For example, the encapsulation layer 600 may be the encapsulation layer 600 in any one of the above embodiments, and the encapsulation layer 600 may include the first encapsulation layer 610, the second encapsulation layer 620, and the third encapsulation layer 630 in any one of the above embodiments, in which reference may be made to any one of the above embodiments for the relative positional relationship between the first encapsulation layer 610 and the second pixel definition portion 330 and the relative positional relationship between the second encapsulation layer 620 and the second pixel definition portion 330.

The embodiments of the present application further provide a display apparatus including the display panel 10 according to any one of the above embodiments. Since the display apparatus according to the embodiments of the present application includes the display panel 10 according to any one of the above embodiments, the display apparatus according to the embodiments of the present application has the beneficial effects of the display panel 10 according to any one of the above embodiments, which will not be repeated herein.

The display apparatus in the embodiments of the present application includes, but is not limited to, a cellular phone, a Personal Digital Assistant (PDA), a tablet computer, an e-book, a television, an entrance guard, a smart fixed-line phone, a console, and other apparatus with display function.

As shown in FIG. 10, and FIG. 1 to FIG. 9, the embodiments of the present application further provide a method for manufacturing a display panel 10, the display panel 10 manufactured by the method may be the display panel 10 in any one of the above embodiments, and the method includes the following steps S01-S03.

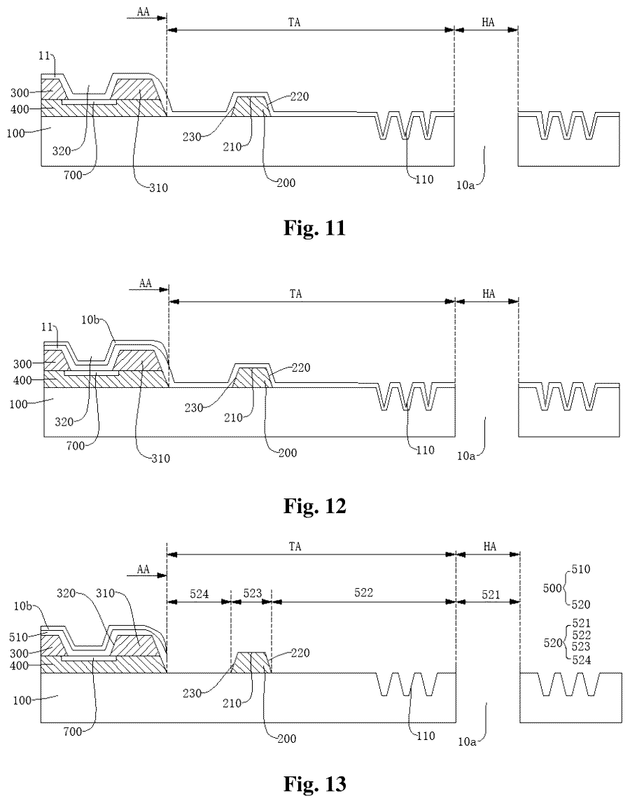

Step S01: as shown in FIG. 11, arranging a dam structure 200 and a light-emitting material layer 11 in sequence on a substrate 100.

Optionally, the display panel 10 includes a display area AA, an aperture area HA, and a transition area TA surrounding at least a portion of the aperture area HA, and the dam structure may be disposed in the transition area TA.

Optionally, step S01 may further include: arranging a planarization layer 400, the dam structure 200, a pixel definition layer 300, and the light-emitting material layer 11 in sequence on the substrate 100, perforating the pixel definition layer 300 to form a first pixel definition portion 310 and a pixel opening 320, at least a portion of a hollow portion further being located at a side of the dam structure 200 away from the substrate 100, or at least a portion of the hollow portion further being located between the dam structure 200 and the display area AA.

Optionally, the substrate 100 includes an isolation groove 110 at a side facing a light-emitting layer 500, and the isolation groove 110 can be configured to restrict extension of a crack, so that the crack is less likely to extend to the display area AA, so as to increase the operational reliability of the display panel 10.

Step S02: as shown in FIG. 12, arranging a photoresist 10b at a side of the light-emitting material layer 11 located in the display area AA away from the substrate 100.

There are various ways for arranging the photoresist 10b at the side of the light-emitting material layer 11 located in the display area AA away from the substrate 100. For example, a photoresist material layer may be first disposed at the side of the light-emitting material layer 11 located in the display area AA away from the substrate 100, and the photoresist material layer is exposed to form the photoresist 10b.

Step S03: as shown in FIG. 13, patterning the light-emitting material layer 11 to form a body portion 510 of the light-emitting layer 500, so that portions of the light-emitting material layer 11 located in the aperture area HA and located between the dam structure 200 and the aperture area HA are removed to form a first vacant segment 521 and a second vacant segment 522.

There are various ways for patterning the light-emitting material layer 11 not covered by the photoresist 10b. For example, the light-emitting material layer 11 not covered by the photoresist 10b may be patterned by developing and etching processes to form a hollow portion 520 penetrating through the body portion 510.

Optionally, the hollow portion 520 may further include a third vacant segment 523, and at least a portion of the dam structure 200 is exposed from the third vacant segment 523, or the hollow portion 520 may further include a fourth vacant segment 524 located between the dam structure 200 and the display area AA.

By arranging the first vacant segment 521, the second vacant segment 522, the third vacant segment 523, and the fourth vacant segment 524, the external moisture in the aperture area HA can be better restricted from diffusing into the display panel 10, and the interference of the external moisture on the operation of the display panel 10 is reduced.

In some optional embodiments, after step S03, the method further includes the following steps S04-S06.

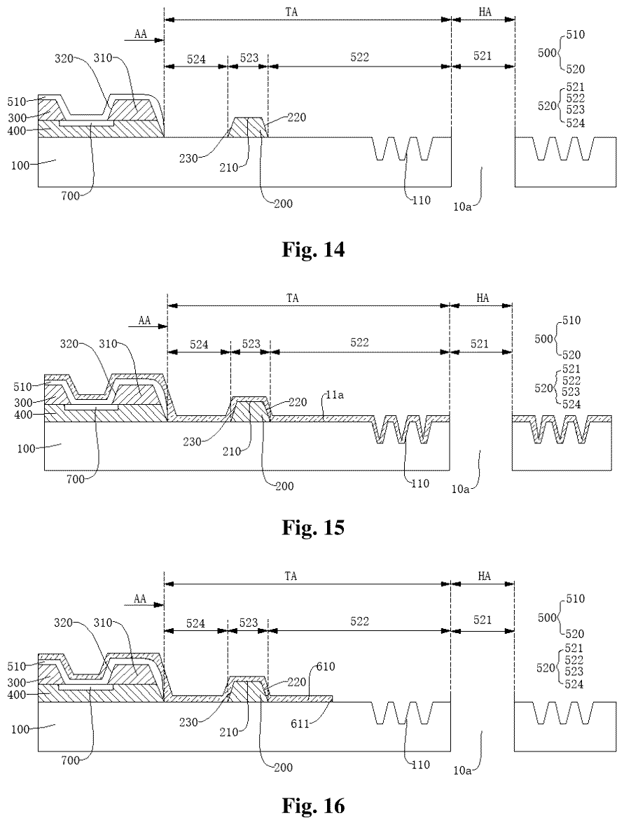

Step S04: as shown in FIG. 14, removing the photoresist 10b.

Step S05: as shown in FIG. 15, arranging a first encapsulation material layer 11a at a side of the light-emitting layer 500 away from the substrate 100.

Optionally, the material of the first encapsulation material layer 11a may include an inorganic material, for example, the material of the first encapsulation material layer 11a may include silicon oxynitride.

Step S06: as shown in FIG. 16, patterning the first encapsulation material layer 11a to form a first encapsulation layer 610, in which an end portion 611 of the first encapsulation layer 610 at a side facing the aperture area HA is spaced apart from the aperture area HA.

The first encapsulation material layer 11a is patterned to form the first encapsulation layer 610 of which the end portion 611 is spaced apart from the aperture area HA, so that the external moisture in the aperture area HA is less likely to diffuse to the first encapsulation layer 610, and thus the first encapsulation layer 610 is less likely to be affected by the water erosion, thereby improving the encapsulation effect of the first encapsulation layer 610.

Optionally, at least a portion of the isolation groove 110 may be located between the end portion 611 of the first encapsulation layer 610 at the side facing the aperture area HA and the aperture area HA, so that the isolation groove 110 may be configured to restrict the crack from extending to the first encapsulation layer 610, thereby improving the encapsulation effect and encapsulation reliability of the first encapsulation layer 610.

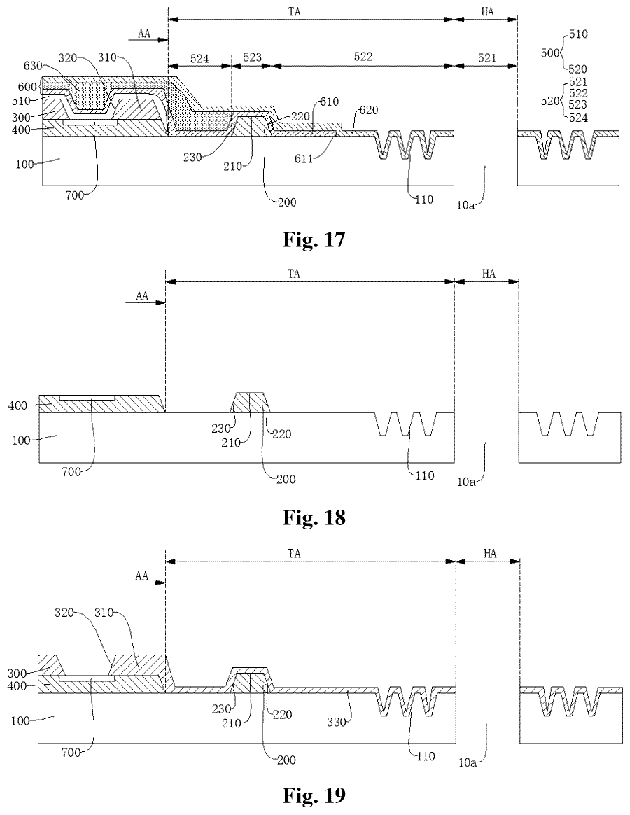

Optionally, after step S06, the method further includes:
step S07: as shown in FIG. 17, arranging a second encapsulation layer 620 at a side of the first encapsulation layer 610 away from the substrate 100, in which at least a portion of the second encapsulation layer 620 covers the substrate 100 between the end portion 611 of the first encapsulation layer 610 at the side facing the aperture area HA and the aperture area HA.

Optionally, the material of the second encapsulation material layer may include an inorganic material, for example, the material of the second encapsulation material layer may include silicon nitride, so that the second encapsulation layer 620 has better stability compared to the first encapsulation layer 610, that is, the second encapsulation layer 620 is less likely to be affected by the moisture, and has better water erosion resistance.

By arranging at least a portion of the second encapsulation layer 620 to cover the substrate 100 between the end portion 611 of the first encapsulation layer 610 at the side facing the aperture area HA and the aperture area HA, the second encapsulation layer 620 can prevent the contact between at least a portion of the external moisture and the first encapsulation layer 610, so that the external moisture is further less likely to affect the encapsulation effect of the first encapsulation layer 610.

Optionally, step S07 may further include: arranging a third encapsulation layer 630 and the second encapsulation layer 620 in sequence at the side of the first encapsulation layer 610 away from the substrate 100, in which the third encapsulation layer 630 may be located at a side of the dam structure 200 facing the display area AA.

The encapsulation layer 600 includes the first encapsulation layer 610, the second encapsulation layer 620, and the third encapsulation layer 630. Optionally, the material of the third encapsulation layer 630 may include an organic material, and the third encapsulation layer 630 may adjust the overall thickness of the encapsulation layer 600, so that the surface of the encapsulation layer 600 away from the substrate 100 is smoother. The dam structure 200 may be configured to block the material of the third encapsulation layer 630, so that the material of the third encapsulation layer 630 is less likely to flow towards the aperture area HA.

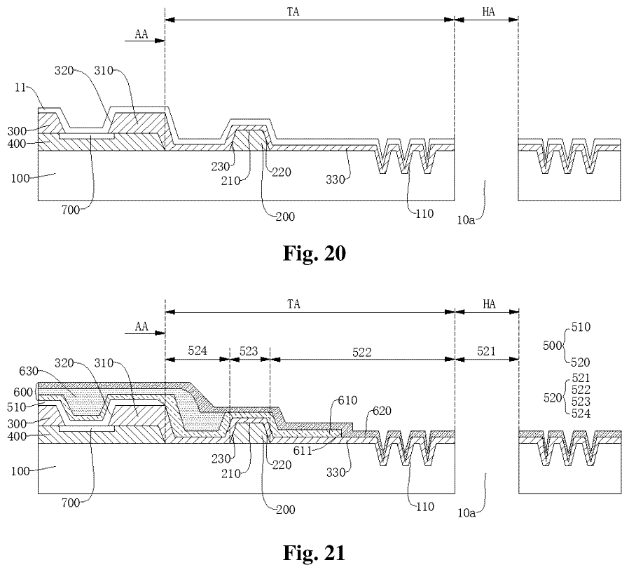

In some optional embodiments, step S01 may further include:
step S011: as shown in FIG. 18, manufacturing the dam structure 200 on the substrate 100;
step S012: as shown in FIG. 19, manufacturing the pixel definition layer 300 on the substrate 100, in which the pixel definition layer 300 includes a second pixel definition portion 330 located in the transition area TA, the first pixel definition portion 310 located in the display area AA, and the pixel opening 320 enclosed and formed by the first pixel definition portion 310, and the transition area TA is located between the display area AA and the aperture area HA;
step S013: as shown in FIG. 20, manufacturing the light-emitting material layer 11 on the pixel definition layer 300.

In the optional embodiment, the second pixel definition portion 330 located in the transition area TA may also be configured to restrict the external moisture in the aperture area HA from intruding into the display area AA. Herein, after step S013, the above steps S02 to S07 may be performed to obtain the display panel 10 as shown in FIG. 21, which may be the display panel 10 in any one of the above embodiments. For example, a portion of the second pixel definition portion 330 may be located at a side of the dam structure 200 away from the substrate 100, the second pixel definition portion 330 may extend from a side of the dam structure 200 facing the display area AA to a side of the dam structure 200 facing the aperture area HA, and by arranging the second pixel definition portion 330 to extend to the dam structure 200, the restriction effect of the second pixel definition portion 330 on the water vapor can be further improved. For example, a second air hole 330a may be disposed in the second pixel definition portion 330 located at the side of the dam structure 200 away from the substrate 100, so that gas under the pixel definition layer 300 may be exhausted through the second air hole 330a in the manufacturing process of the display panel 10. As another example, reference may be made to any one of the above embodiments for the relative positional relationship between the first encapsulation layer 610 and the second pixel definition portion 330 and the relative positional relationship between the second encapsulation layer 620 and the second pixel definition portion 330.

What is claimed is:

1. A display panel, having a display area, an aperture area, and a transition area surrounding at least a portion of the aperture area, and the display panel further comprising:
a substrate;
a dam structure disposed on the substrate and located in the transition area, and the dam structure being disposed surrounding at least a portion of the aperture area; and
a light-emitting layer disposed on the substrate and comprising a body portion located in the display area and a hollow portion penetrating through the body portion, and the hollow portion comprising a first vacant segment formed by a disconnect of the body portion in the aperture area and a second vacant segment located between the dam structure and the aperture area.

2. The display panel according to claim 1, wherein
the transition area surrounds the aperture area and is located between the aperture area and the display area; and
the display panel comprises a via or a blind via located in the aperture area.

3. The display panel according to claim 1, wherein the hollow portion further comprises a third vacant segment, and the dam structure is exposed from the third vacant segment;
the third vacant segment is disposed surrounding at least a portion of the second vacant segment; and
the third vacant segment is communicated with the second vacant segment.

4. The display panel according to claim 1, wherein the hollow portion further comprises a fourth vacant segment located between the dam structure and the display area; and
the fourth vacant segment is disposed surrounding at least a portion of the second vacant segment.

5. The display panel according to claim 1, wherein
the display panel further comprises a first electrode layer disposed at a side of the light-emitting layer away from the substrate, and the first electrode layer is disconnected at least in the aperture area to form a portion located outside the aperture area; and
the first electrode layer is disconnected in the transition area to form a portion located only in the display area.

6. The display panel according to claim 1, wherein the display panel further comprises an encapsulation layer disposed at a side of the light-emitting layer away from the substrate, and the encapsulation layer comprises a first encapsulation layer and a second encapsulation layer disposed at a side of the first encapsulation layer away from the substrate;
an end portion of the first encapsulation layer at a side facing the aperture area is spaced apart from the aperture area, and at least a portion of the second encapsulation layer covers the substrate between the end portion of the first encapsulation layer at the side facing the aperture area and the aperture area;
a material of the first encapsulation layer comprises silicon oxynitride;
a material of the second encapsulation layer comprises silicon nitride; and
at least one of the first encapsulation layer or the second encapsulation layer extends from the display area to the transition area.

7. The display panel according to claim 6, wherein at least one of a portion of the first encapsulation layer or a portion of the second encapsulation layer is located at a side of the dam structure away from the substrate;
a first air hole is disposed in the encapsulation layer located at the side of the dam structure away from the substrate; and
at least one of the first encapsulation layer or the second encapsulation layer extends from the display area to a side of the dam structure facing the aperture area.

8. The display panel according to claim 6, wherein the substrate comprises an isolation groove at a side facing the light-emitting layer; and
at least a portion of the isolation groove is located between an end portion of the first encapsulation layer at a side facing the aperture area and the aperture area.

9. The display panel according to claim 1, wherein the display panel further comprises a pixel definition layer disposed at one side of the substrate, the pixel definition layer comprises a first pixel definition portion located in the display area and a pixel opening enclosed and formed by the first pixel definition portion, and at least a portion of the body portion is disposed in the pixel opening; and
a material of the pixel definition layer comprises an inorganic material.

10. The display panel according to claim 9, wherein the pixel definition layer further comprises a second pixel definition portion located in the transition area;
a material of the second pixel definition portion comprises an inorganic material;
a material of the second pixel definition portion comprises silicon nitride; and
the second pixel definition portion is connected to the first pixel definition portion, and the second pixel definition portion and the first pixel definition portion are made of a same material and manufactured in a same process.

11. The display panel according to claim 10, wherein a portion of the second pixel definition portion is located at a side of the dam structure away from the substrate;
a second air hole is disposed in the second pixel definition portion located at the side of the dam structure away from the substrate; and
the second pixel definition portion extends from a side of the dam structure facing the display area to a side of the dam structure facing the aperture area.

12. The display panel according to claim 10, wherein the display panel further comprises an encapsulation layer disposed at a side of the light-emitting layer away from the substrate, and at least a portion of the encapsulation layer extends to the transition area and abuts against a surface of the second pixel definition portion at a side away from the substrate;
the encapsulation layer comprises a first encapsulation layer and a second encapsulation layer disposed at a side of the first encapsulation layer away from the substrate, an end portion of the first encapsulation layer at a side facing the aperture area is spaced apart from the aperture area, and at least a portion of the second encapsulation layer is located above the substrate between the end portion of the first encapsulation layer at the side facing the aperture area and the aperture area;
the first encapsulation layer extends from the display area to the transition area, and the first encapsulation layer located in the transition area abuts against at least a portion of the surface of the second pixel definition portion at the side away from the substrate;
the second encapsulation layer located between the end portion of the first encapsulation layer at the side facing the aperture area and the aperture area abuts against at least a portion of the surface of the second pixel definition portion at the side away from the substrate; and
the substrate comprises an isolation groove at a side facing the light-emitting layer, at least a portion of the isolation groove is located between the end portion of the first encapsulation layer at the side facing the aperture area and the aperture area, and a portion of the second pixel definition portion is stacked with and abuts against the second encapsulation layer within the isolation groove.

13. A display panel having a display area, an aperture area, and a transition area surrounding at least a portion of the aperture area, and the display panel further comprising:
a substrate;
a pixel definition layer disposed at one side of the substrate and comprising a first pixel definition portion located in the display area, a pixel opening enclosed and formed by the first pixel definition portion, and a second pixel definition portion located in the transition area;
an isolation structure disposed at one side of the first pixel definition portion located in the display area;
a dam structure disposed on the substrate and located in the transition area, and the dam structure being disposed surrounding at least a portion of the aperture area; and
a light-emitting layer disposed on the substrate; and
an encapsulation layer disposed at a side of the light-emitting layer away from the substrate and comprising a first encapsulation layer, and at least a portion of the first encapsulation layer being located in the transition area and abutting against a surface of the second pixel definition portion at a side away from the substrate.

14. The display panel according to claim 13, wherein the first encapsulation layer extends from the display area to the transition area;
a portion of the first encapsulation layer is located at a side of the dam structure away from the substrate;
a first air hole is disposed in the first encapsulation layer located at the side of the dam structure away from the substrate; and
the first encapsulation layer extends from the display area to a side of the dam structure facing the aperture area.

15. The display panel according to claim 13, wherein the encapsulation layer further comprises a second encapsulation layer disposed at a side of the first encapsulation layer away from the substrate, an end portion of the first encapsulation layer at a side facing the aperture area is spaced apart from the aperture area, and at least a portion of the second encapsulation layer is located above the substrate between the end portion of the first encapsulation layer at the side facing the aperture area and the aperture area and abuts against a surface of the second pixel definition portion at a side away from the substrate;
the second encapsulation layer extends from the display area to the transition area;
a portion of the second encapsulation layer is located at a side of the dam structure away from the substrate;
a first air hole is disposed in the second encapsulation layer located at the side of the dam structure away from the substrate; and
the second encapsulation layer extends from the display area to a side of the dam structure facing the aperture area.

16. The display panel according to claim 13, wherein a material of the pixel definition layer comprises an inorganic material;
a material of the second pixel definition portion comprises an inorganic material;
a material of the second pixel definition portion comprises silicon nitride; and
the second pixel definition portion is connected to the first pixel definition portion, and the second pixel definition portion and the first pixel definition portion are made of a same material and manufactured in a same process.

17. A method for manufacturing a display panel, comprising:
arranging a dam structure and a light-emitting material layer in sequence on a substrate;
arranging a photoresist at a side of the light-emitting material layer located in a display area away from the substrate; and
patterning the light-emitting material layer to form a body portion of a light-emitting layer, so that portions of the light-emitting material layer located in an aperture area and located between the dam structure and the aperture area are removed to form a first vacant segment and a second vacant segment.

18. The method according to claim 17, further comprising, after the patterning the light-emitting material layer to form the body portion of the light-emitting layer, so that the portions of the light-emitting material layer located in the aperture area and located between the dam structure and the aperture area are removed to form the first vacant segment and the second vacant segment:
removing the photoresist;
arranging a first encapsulation material layer at a side of the light-emitting layer away from the substrate; and
patterning the first encapsulation material layer to form a first encapsulation layer, and an end portion of the first encapsulation layer at a side facing the aperture area being spaced apart from the aperture area.

19. The method according to claim 18, further comprising, after the patterning the first encapsulation material layer to form the first encapsulation layer, and the end portion of the first encapsulation layer at the side facing the aperture area being spaced apart from the aperture area:
arranging a second encapsulation layer at a side of the first encapsulation layer away from the substrate, and at least a portion of the second encapsulation layer covering the substrate between the end portion of the first encapsulation layer at the side facing the aperture area and the aperture area.

20. The method according to claim 17, wherein the arranging the dam structure and the light-emitting material layer in sequence on the substrate comprises:
manufacturing the dam structure on the substrate;
manufacturing a pixel definition layer on the substrate, the pixel definition layer comprising a second pixel definition portion located in a transition area, a first pixel definition portion located in the display area, and a pixel opening enclosed and formed by the first pixel definition portion, and the transition area being located between the display area and the aperture area; and
manufacturing the light-emitting material layer on the pixel definition layer;
wherein a portion of the second pixel definition portion is located at a side of the dam structure away from the substrate;
a second air hole is disposed in the second pixel definition portion located at the side of the dam structure away from the substrate; and
the second pixel definition portion extends from a side of the dam structure facing the display area to a side of the dam structure facing the aperture area.
